(19) United States
(12) Patent Application Publication
(10) Pub. No.: US 2025/0337024 A1
(43) Pub. Date: Oct. 30, 2025

(54) METHOD AND SYSTEM FOR QUANTIFYING A COMPOSITION OF A COMPOSITE BATTERY ELECTRODE

(71) Applicant: Caterpillar Inc., Peoria, IL (US)

(72) Inventors: Karthik SOMASUNDARAM, Sivaganga (IN); Shantanu Suryakant SONTAKKE, Aurangabad (IN); Stephen J, Bangalore North (IN); Matthew BECKNER, Chillicothe, IL (US)

(73) Assignee: Caterpillar Inc., Peoria, IL (US)

(21) Appl. No.: 18/641,070

(22) Filed: Apr. 19, 2024

(51) Int. Cl. H01M 10/42; H01M 10/0525; H01M 10/48

(52) U.S. Cl. CPC H01M 10/425; H01M 10/482; H01M 10/0525; H01M 2010/4271

(57) ABSTRACT

A battery system includes a battery comprising a full cell having a composite electrode with a composition that includes an actual blend ratio of one or more electrode materials; a memory configured to store an optimization table; a measurement circuit coupled to the full cell and configured to measure an actual open circuit voltage (OCV) of the full cell; and at least one processor configured to: calculate a predicted OCV of the full cell that based on the optimization table and one or more optimization parameters, including a predicted blend ratio of the composite electrode, compare the actual OCV with the predicted OCV to generate an error value, compare the error value with a threshold value, determine whether the predicted blend ratio corresponds to the actual blend ratio of the composite electrode based on whether the error value satisfies the threshold value.

### TECHNICAL FIELD

The present disclosure relates generally to lithium ion (Li-ion) batteries and, for example, to evaluating a composition of a composite electrode of an Li-ion battery.

### BACKGROUND

Lithium-ion batteries have become the industry standard in both electric mobility and portable electronics applications. Lithium-ion batteries operate based on the movement of lithium ions between a negative electrode, known as an anode electrode, and a positive electrode, known as a cathode electrode. For example, during battery discharging, the cathode electrode may receive lithium ions from the anode electrode (lithiation), and during battery charging, the cathode electrode may provide lithium ions to the anode electrode (delithiation). One parameter for predicting a charge/discharge behavior of a lithium-ion battery is a corresponding open circuit voltage (OCV) curve that defines an equilibrium voltage of a battery cell as a function of a state-of-charge (SOC). An OCV is an electrode potential when no current is flowing because the circuit is open.

The OCV is unique to a composition of the battery cell due to a dependency on thermodynamic properties of active materials found in the anode and the cathode electrodes. A composite electrode (e.g., a blended electrode) may include a blend of two or more materials, including two or more electrode active materials. Each material of the composite electrode may have a respective OCV curve that influences a shape of an overall OCV curve. Each respective OCV curve may represent the OCV as function of SOC. Thus, a battery cell may be characterized or modeled by the overall OCV curve. The overall OCV curve may be unique to the composition of a particular battery and may be used as an input by a controller for predicting the charge/discharge behavior of the battery cell and for estimating other battery parameters, such as state-of-health (SOH).

In order to specify the overall OCV curve with high accuracy, it is advantageous to identify the contributions of the individual active materials of each battery electrode to the overall OCV curve. Thus, an exact composition of each electrode may be needed to model a battery cell correctly. However, it may be difficult to determine a composition of each battery electrode, especially for a composite electrode that is a blend of two or more active materials. Typically, an exact composition of an electrode, including which materials are present in the electrode and quantities (e.g., percentages) of those materials, is not known. Furthermore, a quantity of lithium present at an electrode may change based on the SOC. Determining a composition of an electrode may not always be possible due to lack of access to individual components (e.g., chemical composition) or due to a lengthy characterization time needed for obtaining each individual OCV curve. In other instances, a complete tear down of a battery cell may be performed to determine a composition of one or both electrodes.

U.S. Patent Publication No. US 2021/0159552 A1 (the '552 application) to Gorlin et al., filed on Nov. 27, 2019, involves a method for generating battery characteristics for a battery having a target composition that includes identifying open-circuit potential (OCP) characteristics for two similar battery compositions having different proportions of elements. The OCP characteristics in the '552 application are converted to dQ/dV characteristics and linearly combined to derive a target dQ/dV characteristic. The target dQ/dV characteristic is integrated to derive a target OCP characteristic. A battery constructed of the target composition is operated according to the target OCP characteristic. However, system of the '552 application does not provide a method for determining a composition of a composite electrode of a battery cell when the composition of the composite electrode is not known.

The battery system of the present disclosure solves one or more of the problems set forth above and/or other problems in the art. For example, the battery system may provide a method for determining a composition of a composite electrode of a battery cell and/or determining one or more optimization parameters used in a battery model.

### SUMMARY

In some implementations, a battery system includes a battery comprising a full cell having a composite electrode with a composition that includes an actual blend ratio of one or more electrode materials; a measurement circuit coupled to the full cell and configured to measure an actual OCV of the full cell; a memory configured to store a physics-based model for a half-cell comprising a working electrode, and an optimization table; and at least one processor configured to: simulate, for each different electrode composition of a plurality of different electrode compositions of the working electrode, the physics-based model with zero current for a first SOC until a half-cell potential reaches a first steady state potential, determine, for each different electrode composition of the plurality of different electrode compositions of the working electrode, a first state-of-lithiation (SOL) of each material of the different electrode composition based on the first steady state potential, store, in the optimization table for each different electrode composition, the first SOL of each material of the different electrode composition in a first respective table entry linked to the different electrode composition, calculate a predicted OCV of the full cell based on the optimization table and one or more optimization parameters that include a predicted blend ratio of the composite electrode, compare the actual OCV with the predicted OCV to generate an error value, compare the error value with a threshold value, determine whether the predicted blend ratio corresponds to the actual blend ratio of the composite electrode based on whether the error value satisfies the threshold value, and configure the measurement circuit with the predicted blend ratio based on the error value satisfying the threshold value.

In some implementations, a battery system includes a battery comprising a full cell having a composite electrode with a composition that includes an actual blend ratio of one or more electrode materials; a memory configured to store an optimization table, including a plurality of different electrode compositions for a working electrode of a half-cell and, for each different electrode composition, an SOL of each material of the different electrode composition associated with a steady state potential obtained at an SOC; a measurement circuit coupled to the full cell and configured to measure an actual OCV of the full cell; and at least one processor configured to: calculate a predicted OCV of the full cell that based on the optimization table and one or more optimization parameters, including a predicted blend ratio of the composite electrode, compare the actual OCV with the predicted OCV to generate an error value, compare the error value with a threshold value, determine whether the predicted blend ratio corresponds to the actual blend ratio of the composite electrode based on whether the error value satisfies the threshold value, and configure the measurement circuit with the predicted blend ratio based on the error value satisfying the threshold value.

In some implementations, a method includes measuring, by a controller, an actual OCV of a full cell of a battery; calculating, by the controller, a predicted OCV of the full cell based on an optimization table and one or more optimization parameters, including a predicted blend ratio of a composite electrode of the full cell; comparing, by the controller, the actual OCV with the predicted OCV to generate an error value; comparing, by the controller, the error value with a threshold value; determining, by the controller, whether the predicted blend ratio corresponds to an actual blend ratio of the composite electrode based on whether the error value satisfies the threshold value; configuring, by the controller, a battery monitoring system with the predicted blend ratio as the actual blend ratio based on the error value satisfying the threshold value, including setting a parameter value of each optimization parameter used for calculating the predicted blend ratio that corresponds to the actual blend ratio as an actual parameter value of the full cell; receiving, by the controller, an electrical response from the full cell in response to an electrical stimulus; and determining, by the controller, an SOH of the full cell based on the electrical response received from the full cell and based on each actual parameter value of the full cell.

### BRIEF DESCRIPTION OF THE DRAWINGS

FIG. 1 is a diagram of an example battery pack.

FIG. 2 is a diagram of a battery system.

FIG. 3 is a flow diagram of a method performed by a measurement circuit for evaluating a composition of a composite electrode of an Li-ion battery cell.

FIG. 4 shows an example optimization table.

FIG. 5 is a flow diagram of a method performed by a measurement circuit for evaluating a composition of a composite electrode of an Li-ion battery cell.

FIG. 6 is a flow diagram of a method of calculating an SOH based on a composition of a composite electrode of a full cell.

FIG. 7 is a flowchart of an example process associated with method and system for quantifying a composition of a composite battery electrode.

### DETAILED DESCRIPTION

This disclosure relates to a battery system, which is applicable to any electric machine or electric device that uses a battery, such as an Li-ion battery, as a power source for operation.

The battery system may provide a method for determining a composition of a composite electrode of a battery cell in an efficient manner without a tear down of the battery cell. Thus, the battery system may provide a noninvasive method for determining the composition of the composite electrode. Additionally, the battery system may determine the composition of the composite electrode without measuring individual OCV curves of each electrode material of the battery cell, thereby avoiding lengthy characterization times needed for obtaining each individual OCV curve and reducing an overall evaluation time.

In some implementations, the battery system may determine, based on the composition of the composite electrode, one or more optimization parameters to generate a physics-based model of the battery cell, which may include an overall OCV curve. The method may be employed by a battery management system (BMS) that utilizes the overall OCV curve to provide estimates of one or more battery parameters or as part of a battery design interface that uses a library of OCV properties of active materials or electrode blends. The battery parameters may include remaining battery capacity, power limits, SOH, and other characteristics.

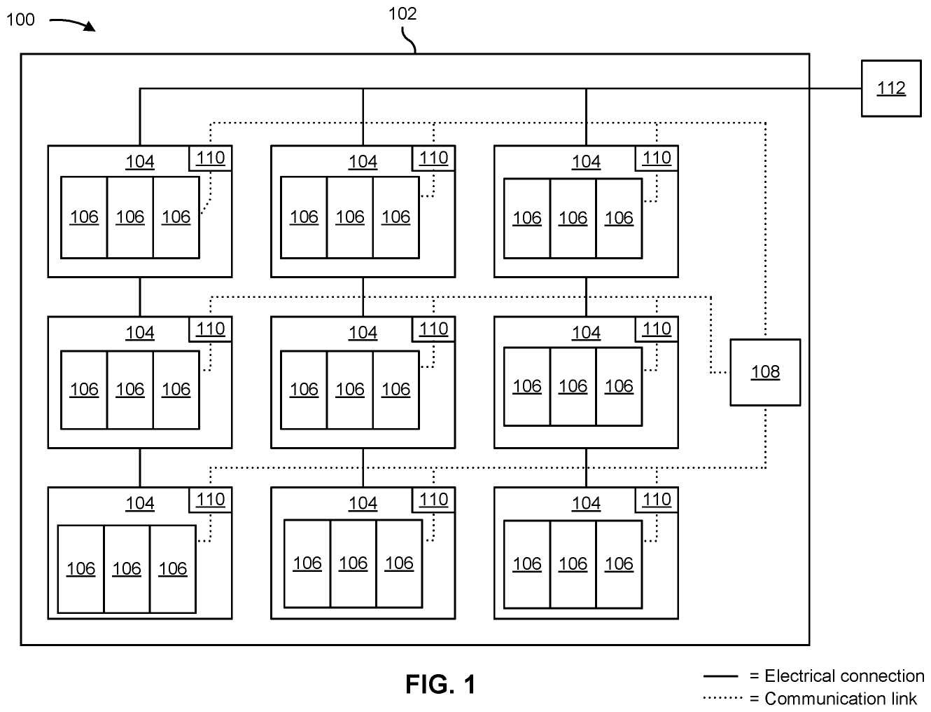

FIG. 1 is a diagram of an example battery pack 100. The battery pack 100 may include a battery pack housing 102, one or more battery modules 104, and one or more battery cells 106. The battery pack 100 includes a battery pack controller 108 associated with storing information and/or controlling one or more operations associated with the battery pack 100. The battery pack controller 108 may a controller of a BMS. For example, the battery pack controller 108 may be an electronic control module (ECM) of the BMS. The battery pack controller 108 may be configured to measure one or more characteristics of the battery cells 106 to determine one or more battery parameters. In some cases, the battery pack controller 108 may be provided external to the battery pack housing 102. Each battery module 104 includes a module controller 110 associated with storing information and/or controlling one or more operations associated with the battery module 104.

The battery pack 100 may be associated with a component 112. The component 112 may be powered by the battery pack 100. For example, the component 112 can be a load that consumes energy provided by the battery pack 100, such as electronics or an electric motor, among other examples. As another example, the component 112 provides energy to the battery pack 100 (e.g., to be stored by the battery cells 106). In such examples, the component 112 may be a power generator, a solar energy system, and/or a wind energy system, among other examples. As another example, the component 112 may charge and discharge one or more battery cells 106 of the battery pack 100. In such examples, the component 112 may be a switched-mode power supply (SMPS), a DC-to-DC converter (e.g., a buck-boost converter), or an electric vehicle.

The battery pack housing 102 may include metal shielding (e.g., steel, aluminum, or the like) to protect elements (e.g., battery modules 104, battery cells 106, the battery pack controller 108, the module controllers 110, wires, circuit boards, or the like) positioned within battery pack housing 102. Each battery module 104 includes one or more (e.g., a plurality of) battery cells 106 (e.g., positioned within a housing of the battery module 104). Battery cells 106 may be connected in series and/or in parallel within the battery module 104 (e.g., via terminal-to-busbar welds). Each battery cell 106 is associated with a chemistry type. The chemistry type may be lithium ion (Li-ion) (e.g., lithium ion polymer).

The battery modules 104 may be arranged within the battery pack 100 in one or more strings. For example, the battery modules 104 are connected via electrical connections, as shown in FIG. 1. The electrical connections may be removable, such as via bolts and/or nuts at one or more terminals on housings of the battery modules 104. The battery modules 104 may be connected in series and/or in parallel. For example, a number of battery modules 104 may be connected in series to provide a particular voltage (e.g., to the component 112). Alternatively, a number of battery modules 104 may be connected in parallel to increase a current and/or a power output of the battery pack 100. The number of battery cells 106 included in each battery module 104, and the number of battery modules 104 included in the battery pack 100 (e.g., and the relative serial and/or parallel connections of the battery cells 106 and/or the battery modules 104) may be associated with the required output power and an intended use of the battery pack 100. For example, any number of battery cells 106 can be included in a battery module 104. Similarly, any number of battery modules 104 can be included in the battery pack 100.

The battery pack controller 108 is communicatively connected (e.g., via a communication link) to each module controller 110. The battery pack controller 108 may be associated with receiving, generating, storing, processing, providing, and/or routing information associated with the battery pack 100. The battery pack controller 108 may also be referred to as a battery pack management device or system. The battery pack controller 108 may communicate with the component 112 and/or a controller of the component 112, may control a start-up and/or shut-down procedure of the battery pack 100, may monitor a current and/or a voltage of one or more battery cells 106, may monitor a current and/or voltage of a string (e.g., of battery modules 104), and/or may monitor and/or control a current and/or voltage provided by the battery pack 100, among other examples. A module controller 110 may be associated with receiving, generating, storing, processing, providing, and/or routing information associated with a battery module 104. The module controller 110 may communicate with the battery pack controller 108.

The battery pack controller 108 and/or a module controller 110 may be associated with monitoring and/or determining an OCV, an SOL, an SOC, an SOH, a depth of discharge (DOD), an output voltage, a temperature, and/or an internal resistance and impedance, among other examples, associated with a battery cell 106, associated with a battery module 104, and/or associated with the battery pack 100. Additionally, or alternatively, the battery pack controller 108 and/or the module controller 110 may be associated with monitoring, controlling, and/or reporting one or more parameters associated with battery cells 106. The one or more parameters may include cell voltages, temperatures, chemistry types, a cell energy throughput, a cell internal resistance, and/or a quantity of charge-discharge cycles, among other examples. Additionally, the battery pack controller 108 and/or a module controller 110 may be associated with performing an electrode balancing for determining a composition, including a blend percentage of active materials, of a composite electrode of a battery cell 106.

The battery pack controller 108 and/or a module controller 110 includes one or more processors and/or one or more memories. A processor may include a central processing unit, a microprocessor, a controller, a microcontroller, a digital signal processor, a field-programmable gate array, an application-specific integrated circuit, and/or another type of processing component. The processor may be implemented in hardware, firmware, or a combination of hardware and software. In some implementations, the processor may include one or more processors capable of being programmed to perform one or more operations or processes described elsewhere herein. A memory may include volatile and/or nonvolatile memory. For example, the memory may include random access memory (RAM), read only memory (ROM), and/or another type of memory (e.g., a flash memory, a magnetic memory, and/or an optical memory). The memory may include internal memory (e.g., RAM, ROM, or a hard disk drive) and/or removable memory (e.g., removable via a universal serial bus connection). The memory may be a non-transitory computer-readable medium. The memory may store information, one or more instructions, and/or software (e.g., one or more software applications) related to the operation of the battery pack 100, a battery module 104, and/or a battery cell 106. The memory may include one or more memories that are coupled (e.g., communicatively coupled) to the processor, such as via a bus. Communicative coupling between a processor and a memory may enable the processor to read and/or process information stored in the memory and/or to store information in the memory.

The battery pack controller 108 may be configured to evaluate a composition or one or more composite electrodes of a battery cell 106. The battery cells 106 may be Li-ion battery cells. A Li-ion battery is an electrochemical device that stores/delivers electrical energy through a reversible intercalation reaction in which lithium ions (Li+) are shuttled between two dissimilar electrode materials separated by a lithium ion conducting electrolyte solution. An Li-ion battery cell (e.g., a full cell) may include a cathode current collector, an anode current collector, a cathode composite electrode arranged adjacent to the cathode current collector, an anode composite electrode arranged adjacent to the anode current collector, an electrolyte solution disposed between the cathode current collector and the anode current collector, and a porous separator arranged between the cathode composite electrode and the anode composite electrode.

The cathode current collector and the anode current collector are conductive foils at each electrode of the Li-ion battery cell that are connected to positive and negative terminals of the Li-ion battery cell, respectively. The positive and negative terminals of the Li-ion battery cell may be coupled to a load (e.g., component 112) via an external circuit. During operation (e.g., during charging or discharging), lithium ions move between the cathode and the anode internally, whereas electrons move through the external circuit in a direction that is opposite to a movement of the lithium ions. For example, while the Li-ion battery cell is discharging, the anode composite electrode releases lithium ions to the cathode composite electrode, generating a flow of electrons that provides electrical current to load. When the Li-ion battery cell is charging, lithium ions are released by the cathode composite electrode and received by the anode composite electrode by moving through the electrolyte. The porous separator may be a porous polymeric film that separates the cathode composite electrode and the anode composite electrode while enabling an exchange of lithium ions from one composite electrode to the other composite electrode.

The cathode composite electrode may be made of a lithium-metal oxide composite. For example, a cathode material of the cathode composite electrode may include lithium cobalt oxide (LiCoO₂), lithium manganese oxide (LiMn₂O₄), lithium iron phosphate (LiFePO₄ or LFP), or lithium nickel manganese cobalt oxide (LiNiMnCoO₂ or NMC). An anode material of the anode composite electrode may be made of a carbon-based material, such as graphite, silicon, or a combination of graphite and silicon. Thus, the anode composite electrode may be made of carbon-based composite. As a result, each composite electrode has a blended composite of electrode material that facilitates the reversible intercalation reaction.

A half-cell is a single electrode in an electrochemical cell. For example, a lithium battery half-cell may include a reference electrode (e.g., a lithium metal foil), an electrode current collector, a composite electrode (e.g., a working electrode) arranged adjacent to the electrode current collector, a porous separator arranged adjacent to the lithium metal foil, and an electrolyte solution disposed between the lithium metal foil and the electrode current collector. An electrode potential of the lithium battery half-cell may be determined by the energy required to move lithium ions from the composite electrode to the lithium metal foil, and vice versa. Thus, the electrode potential of the lithium battery half-cell may determine the energy required to move lithium ions between the lithium metal foil and the composite electrode.

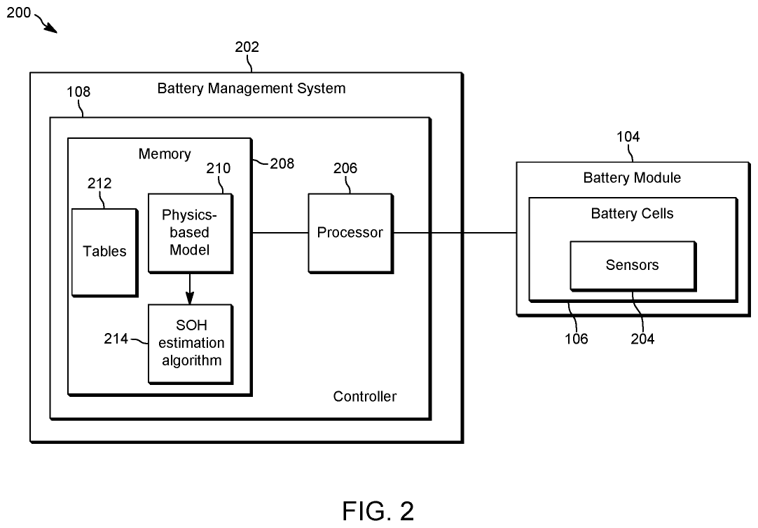

FIG. 2 is a diagram of a battery system 200. The battery system 200 may be part of the battery pack 100. The battery system 200 includes a battery monitoring system 202 and a battery module 104. The battery module 104 incudes one or more battery cells 106 (e.g., full cells) and one or more sensors 204 that may sense one or more parameters of the battery module 104 and/or one or more parameters of individual battery cells 106. Thus, the battery module 104 includes at least one full cell having a composite electrode with a composition that includes an actual blend ratio of one or more electrode materials. The composite electrode may be a cathode electrode or an anode electrode of a lithium-ion battery.

The battery monitoring system 202 includes the battery pack controller 108, which may include one or more processors 206 and/or one or more memories 208. In some cases, one or more processors 206 may be provided in the module controller 110. A memory 208 of the battery pack controller 108 may store one or more physics-based models 210, one or more optimization tables 212, and an SOH estimation algorithm 214. The one or more physics-based models may include a physics-based model associated with a half-cell that includes a working electrode. Additionally, the one or more physics-based models may include a physics-based model generated by the one or more processors 206 based on a composition analysis of one or more composite electrodes of the battery module 104. Thus, the one or more physics-based models may include a physics-based half-cell model for performing simulations, and a physics-based full cell model of a battery cell 106 derived from the simulations.

The one or more processors 206 may calculate an SOH of the battery module 104 and/or one or more battery cells 106 based on the SOH estimation algorithm 214 and based on a composition of one or more composite electrodes of the battery module 104. The one or more processors 206 may transmit the SOH to a user interface (e.g., a display) for output to a user.

The one or more sensors 204 and the battery pack controller 108 may form a measurement circuit coupled to a full cell and configured to measure an actual OCV of the full cell, as well as one or more other parameters of the full cell, including SOH.

The physics-based half-cell model may be based on a virtual half-cell that has a virtual working electrode. The virtual working electrode may have a composition of any number of different electrode compositions (e.g., of a defined set of different electrode compositions). The one or more processors 206 may run a simulation on the virtual half-cell for each different electrode composition based on the physics-based half-cell model. The defined set of different electrode compositions may correspond to a set of different electrode compositions of a composite electrode of a full cell that is under evaluation. That is, the composite electrode of the full cell may have a composition made out of any number of different compositions that include different combinations of electrode materials and/or blend ratios (e.g., blend percentages). A real blend ratio of the full cell is referred to as an actual blend ratio and may be defined on volume basis.

The one or more processors 206 may simulate, for each different electrode composition of a plurality of different electrode compositions of the working electrode of the half-cell, the physics-based half-cell model with zero current for a first SOC until a half-cell potential reaches a first steady state potential. The half-cell potential may be an OCV of the half-cell. Each different electrode composition of the plurality of different electrode compositions includes a unique set of materials and blend percentages.

Based on the simulation, the one or more processors 206 may determine, for each different electrode composition of the plurality of different electrode compositions of the working electrode, a first SOL of each material of the different electrode composition based on the first steady state potential. The one or more processors 206 may store, in an optimization table 212 for each different electrode composition, the first SOL of each material of the different electrode composition in a first respective table entry linked to the different electrode composition. Thus, for each different electrode composition of the plurality of different electrode compositions, the one or more processors 206 calculate the first SOL of each material of the different electrode composition as a function of the first SOC and the first steady state potential.

Additionally, the one or more processors 206 may, for each different electrode composition of the plurality of different electrode compositions: simulate the physics-based half-cell model with zero current for a second SOC until the half-cell potential reaches a second steady state potential, determine a second SOL of each material of the different electrode composition based on the second steady state potential, and store, in the optimization table 212, the second SOL of each material of the different electrode composition in a second respective table entry linked to the different electrode composition. The one or more processors 206 may determine a respective SOL for each material for a plurality of different SOCs, and store the respective SOLs for each different electrode composition, linked to a different SOC, in the optimization table 212.

Additionally, the one or more processors 206 may calculate a predicted OCV of the full cell based on the optimization table and one or more optimization parameters that include a predicted blend ratio of the composite electrode. For example, the one or more processors 206 may select one of the different electrode compositions from the optimization table as the predicted blend ratio of the composite electrode, and may use SOL values and associated SOC values along with one or more optimization parameters to calculate the predicted OCV of the full cell. In addition to the predicted blend ratio, the one or more optimization parameters may include at least one of an SOL of an anode electrode of the full cell at 0% SOC of the full cell, a host capacity of an anode electrode of the full cell, a cathode electrode potential of the full cell at 0% SOC, or a cathode electrode potential of the full cell at 100% SOC

Additionally, the one or more processors 206 compare the actual OCV with the predicted OCV to generate an error value, compare the error value with a threshold value, and determine whether the predicted blend ratio corresponds to the actual blend ratio of the composite electrode based on whether the error value satisfies the threshold value. For example, the one or more processors 206 may determine that the predicted blend ratio is the actual blend ratio of the composite electrode based on the error value being less than the threshold value. Alternatively, the one or more processors 206 may determine that the predicted blend ratio is not the actual blend ratio of the composite electrode based on the error value being equal to or greater than the threshold value.

The one or more processors 206 may iteratively calculate the predicted OCV based on the error value not satisfying the threshold value, compare each iteration of the predicted OCV with the actual OCV to generate the error value, and compare each error value with the threshold value to determine which different value set of the one or more optimization parameters satisfies the threshold value. The one or more processors 206 may calculate each iteration of the predicted OCV based on a different value set of the one or more optimization parameters. Thus, the one or more processors 206 iteratively calculate the predicted OCV using different value sets of the one or more optimization parameters until the error value satisfies the threshold value. The one or more processors 206 may iteratively calculate the predicted OCV by changing one or more parameter values of the one or more optimization parameters for each iteration. As a result, the one or more processors 206 may determine which predicted blend ratio provides a predicted OCV that causes the error value to satisfy the threshold value. The predicted blend ratio that provides a predicted OCV that causes the error value to satisfy the threshold value may be determined by the one or more processors 206 as the actual blend ratio of the composite electrode.

Additionally, the one or more processors 206 configure the measurement circuit with the predicted blend ratio based on the error value satisfying the threshold value. For example, the one or more processors 206 may store the predicted blend ratio that provides a predicted OCV that causes the error value to satisfy the threshold value as the actual blend ratio in the one or more memories 208. The predicted blend ratio may be stored as one of the optimization parameters. Additionally, the one or more processors 206 may configure the measurement circuit by setting a parameter value of each optimization parameter used for calculating the predicted blend ratio that corresponds to the actual blend ratio as an actual parameter value of the full cell. The actual parameter value of each optimization parameter may be stored in the one or more memories 208 to be accessed by the one or more processors 206. The one or more processors 206 may determine, based on the composition of the composite electrode, an overall OCV curve of the full cell. The one or more processors 206 may calculate an SOH of the full cell based on each actual parameter value of the full cell stored in the one or more memories 208. Additionally, the one or more processors 206 may generate the physics-based full cell model based on the actual parameter value of each optimization parameter, and may use the physics-based full cell model to determine one or more one or more parameters of the full cell.

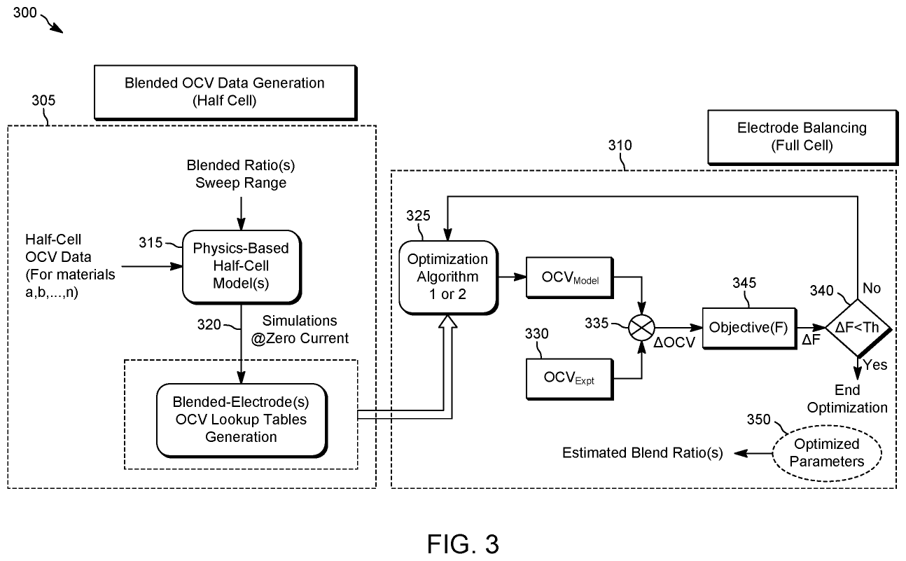

FIG. 3 is a flow diagram of a method 300 performed by a measurement circuit for evaluating a composition of a composite electrode of an Li-ion battery cell. The measurement circuit may include the battery pack controller 108 and/or the module controller 110. The method 300 may include generating blended OCV data based on a half-cell (operation 305) and performing electrode balancing based on a full cell (operation 310).

Generating the blended OCV data may include generating one or more physics-based half-cell models (operation 315). The one or more physics-based half-cell models may be generated based on different blend ratios and based on half-cell OCV data that corresponds to electrode materials of the different blend ratios that may be present in the composite electrode.

The method 300 may include simulating the one or more physics-based half-cell models, for each different electrode composition of a plurality of different electrode compositions of the working electrode, with zero current for one or more SOCs (e.g., one or more SOC levels from in a range of 0% to 100% SOC) in order to generate data for one or more optimization tables (operation 320). A simulation may be performed for each SOC with zero current. Once a half-cell potential reaches a steady state potential for the SOC, the steady state potential may be recorded and used for determining an SOL for each material of an electrode composition under simulation. For example, once the half-cell potential reaches a steady state potential for an SOC at zero current, performing the simulation may include determining, for each different electrode composition of the plurality of different electrode compositions of the working electrode, an SOL of each material of the different electrode composition based on the steady state potential. Additionally, performing the simulation may include storing, in an optimization table for each different electrode composition, the SOL of each material of the different electrode composition in a respective table entry linked to the different electrode composition. The optimization table may be a lookup table used for performing the electrode balancing of the full cell.

Performing electrode balancing based on the full cell may include calculating a predicted OCV (OCV_{Model}) of the full cell based on the optimization table and one or more optimization parameters that include a predicted blend ratio of the composite electrode of the full cell (operation 325). In other words, the predicted blend ratio may be selected from one of the different electrode compositions provided in the optimization table, and the predicted blend ratio may be used for calculating the predicted OCV (OCV_{Model}) according to an optimization algorithm (e.g., optimization algorithm 1 or 2). The optimization algorithm 1 may be applied based on one of the electrodes of the full cell being a composite electrode. The optimization algorithm 2 may be applied based on both of the electrodes of the full cell being composite electrodes. One or more additional optimization parameters, such as the SOL of the anode electrode of the full cell at 0% SOC, the host capacity of the anode electrode of the full cell, the cathode electrode potential of the full cell at 0% SOC, or the cathode electrode potential of the full cell at 100% SOC, may also be used in the optimization algorithm for calculating the predicted OCV (OCV_{Model}). For example, the measurement circuit may select parameter values for each optimization parameter used in the optimization algorithm for calculating the predicted OCV (OCV_{Model}).

Performing electrode balancing based on the full cell may include measuring the actual OCV (OCV_{Expt}) of the full cell (operation 330). For example, the measurement circuit may be connected to the full cell during zero current to measure the actual OCV (OCV_{Expt}) of the full cell. The measurement circuit may use one or more sensors 204 to measure the actual OCV (OCV_{Expt}).

Performing electrode balancing based on the full cell may include comparing the actual OCV (OCV_{Expt}) with the predicted OCV (OCV_{Model}) to generate an error value ΔOVC (operation 335).

Performing electrode balancing based on the full cell may include comparing the error value ΔOVC with a threshold value Th to generate a comparison result (operation 340). In some implementations, a plurality of error values ΔOVC may be sampled and processed according to an objective function (F) to generate an error value ΔF (operation 345). The error value ΔF may be an average of the plurality of error values ΔOVC, a median of the plurality of error values ΔOVC, a sum of squares of the plurality of error values ΔOVC, or another type of aggregating function. Thus, the comparing may include comparing the error value ΔF with the threshold value Th to generate the comparison result.

Comparing the error value ΔOVC or ΔF with the threshold value Th to generate the comparison result may include determining whether the predicted blend ratio corresponds to the actual blend ratio of the composite electrode based on whether the error value ΔOVC or ΔF satisfies the threshold value Th (Yes or No). For example, the predicted blend ratio under test may be determined to be the actual blend ratio of the composite electrode based on the error value ΔOVC or ΔF being less than the threshold value Th (operation 340: Yes). In this case, the measurement circuit may store a parameter value of each optimization parameter used for calculating the predicted blend ratio that corresponds to the actual blend ratio as an actual parameter value of the full cell (operation 350). Alternatively, the predicted blend ratio under test may be determined to not be the actual blend ratio of the composite electrode based on the error value ΔOVC or ΔF being equal to or greater than the threshold value Th (operation 340: No). In this case, the measurement circuit may select a different set of optimization parameters to generate another predicted OCV (OCV_{Model}), and the electrode balancing repeats until a set of optimization parameters is found that satisfies the threshold value Th. Thus, the electrode balancing includes iteratively calculating the predicted OCV (OCV_{Model}) using different value sets of the one or more optimization parameters until the error value ΔOVC or ΔF satisfies (e.g., is less than) the threshold value Th.

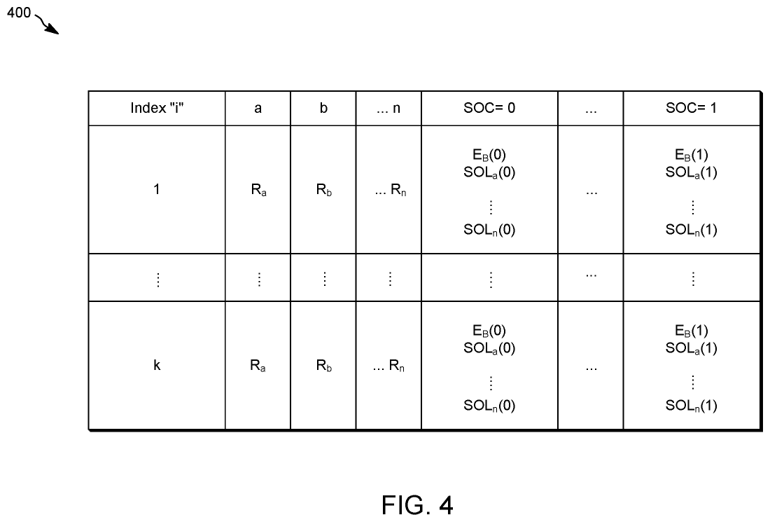

FIG. 4 shows an example optimization table 400. The optimization table 400 may be generated based on operation 320 described in connection with FIG. 3. In the optimization table 400, indices i=0, . . . , k, represent a number of different electrode compositions simulated in operation 320. a, b, . . . , n represent the different electrode materials present in a composite electrode (e.g., a blended electrode). Thus, a, b, . . . , n represent the different electrode materials of an electrode composition for each index i. Rₐ, R_{b}, . . . , Rₙ represent respective blend percentages of each electrode material of a composition such that Rₐ+R_{b}+ . . . +Rₙ=100% for all indices i=0, . . . , k. E_{B}(SOC) represents the equilibrium potential (e.g., a steady state potential) of the composite electrode at a particular SOC, where 0≤SOC≤1 (e.g., with 0 representing 0% SOC and 1 representing 100% SOC). SOLⱼ(SOC) (j=a, b, . . . , n) defines the state-of-lithiation of each respective electrode material at the equilibrium potential E_{B}(SOC) at a particular SOC. Thus, an equilibrium potential and an SOL for each electrode material of an electrode composition is recorded for each index i and at different SOCs for the index i.

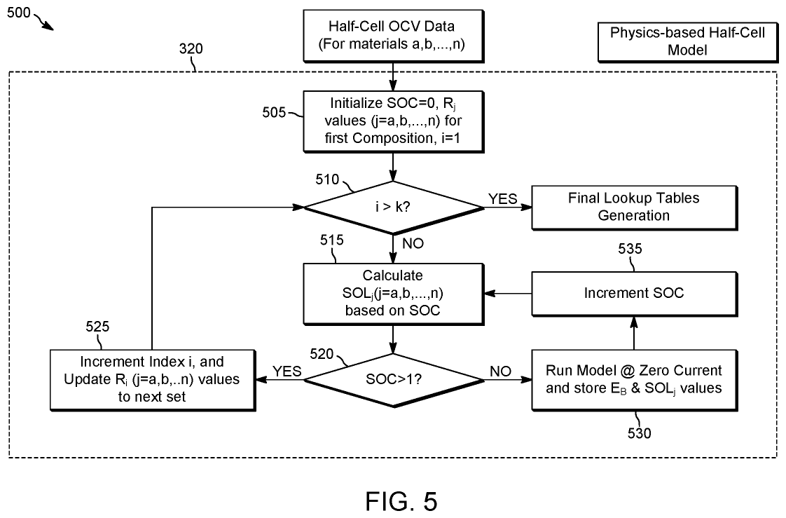

FIG. 5 is a flow diagram of a method 500 performed by a measurement circuit for evaluating a composition of a composite electrode of an Li-ion battery cell. The method 500 may correspond to simulating the physics-based half-cell model with zero current (operation 320) as described in connection with FIG. 3 for generating the optimization table 400.

The method 500 includes initializing SOC=0, Rⱼ values (j=a, b, . . . n) for a first electrode composition (block 505) and the index i to 1, and comparing the index i to k (block 510). If index i is greater than k, the iterations stop, and the optimization table is generated (510: Yes). If index i is not greater than k, a current iteration is performed (510: No).

The method 500 includes calculating the SOLⱼ (j=a, b, . . . n) based on a configured SOC. (block 515), and checking if the SOC is greater than 1 (block 520). If the SOC is greater than 1 (520: Yes), the index i is incremented and the Rⱼ (j=a, b, . . . n) values are updated to next set of materials (e.g., a next electrode composition) (block 525). The method 500 then returns to block 510. If the SOC is equal to or less than 1 (520: No), the physics-based half-cell model is simulated with zero current based on the set of optimization parameters, and values for the equilibrium potential E_{B}(SOC) and SOL; (SOC) values determined during the simulation are recorded (block 530). The SOC is then incremented (block 535), and the method 500 then returns to block 515 for the next SOC value.

In loop 515, 520, 530, and 535, an initial calculation of an SOL based on a particular SOC may assume that an electrode material is a pure electrode (e.g., a non-blended electrode of a single material), and the model simulation may determine an actual SOL of each material forming the composite electrode based on the equilibrium potential E_{B}. For a positive electrode, SOLj may be calculated based on Equation 1. For a negative electrode, SOLj may be calculated based on Equation 2.

$${SOL}_{j} = {SOL}_{min} - ( 1 - SOC ) * ( {SOL}_{max} - {SOL}_{min} ) \qquad Eq . 1$$

$${SOL}_{j} = {SOL}_{min} - ( SOC ) * ( {SOL}_{max} - {SOL}_{min} ) \qquad Eq . 2$$

SOLₘᵢₙ denotes a minimum SOL of a material, and SOLₘₐₓ denotes a maximum SOL of the material.

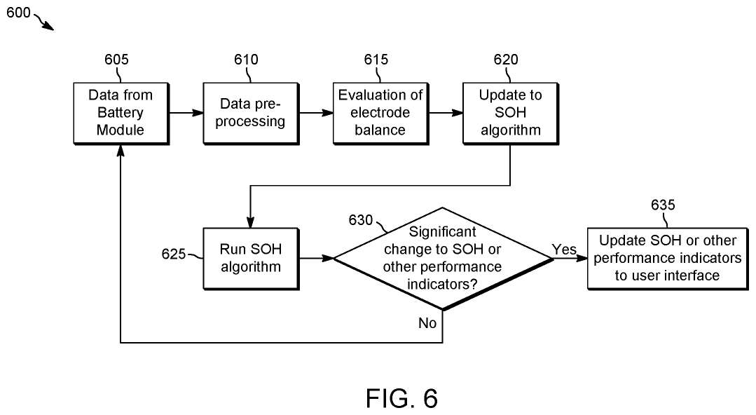

FIG. 6 is a flow diagram of a method 600 of calculating an SOH based on a composition of a composite electrode of a full cell. The method 600 may be performed by a measurement circuit that includes the battery pack controller 108 and/or the module controller 110. The composition of the composite electrode may be determined based on method 300 described in connection with FIG. 3.

The method 600 may include receiving data from a battery module (e.g., battery module 104) (block 605). The data may include an OCV of a full cell.

The method 600 may further include performing data pre-processing, such as filtering, on the data received from the battery module (block 610).

The method 600 may further include performing electrode balancing based on the data received from the battery module to determine the composition of the composite electrode of the full cell (block 615). For example, referring to FIG. 3, a predicted blend ratio under test may be determined to be an actual blend ratio of the composite electrode based on the error value ΔOVC or ΔF being less than the threshold value Th (operation 340: Yes).

The method 600 may further include updating an SOH algorithm based on the composition of the composite electrode (e.g., based on the actual blend ratio) (block 620). Additionally, the SOH algorithm may be updated based on one or more optimization parameters corresponding to the composition of the composite electrode.

The method 600 further includes executing the SOH algorithm to calculate the SOH of the full cell (block 625). Calculating the SOH may include calculating the SOH based on one or more parameters, such as cell voltages, temperatures, chemistry types, a cell energy throughput, a cell internal resistance, and/or a quantity of charge-discharge cycles, among other examples. Calculating the SOH may include receiving an electrical response from the full cell in response to an electrical stimulus, and determining the SOH of the full cell based on the electrical response received from the full cell and based on each actual parameter value of the full cell, including the actual blend ratio and actual parameter values of one or more optimization parameters corresponding to the composition of the composite electrode.

The method 600 may further include determining whether there has been a significant change to the SOH or other performance indicators (block 630). For example, determining whether there has been a significant change to the SOH may include comparing a difference between two SOH measurements and comparing the difference to a threshold. If there has been a significant change to the SOH or other performance indicators, the SOH or other performance indicators may be updated at a user interface (block 635). For example, the SOH may be transmitted to the user interface and/or an ECM of a machine.

If there has not been a significant change to the SOH or other performance indicators, the method 600 may return to block 605.

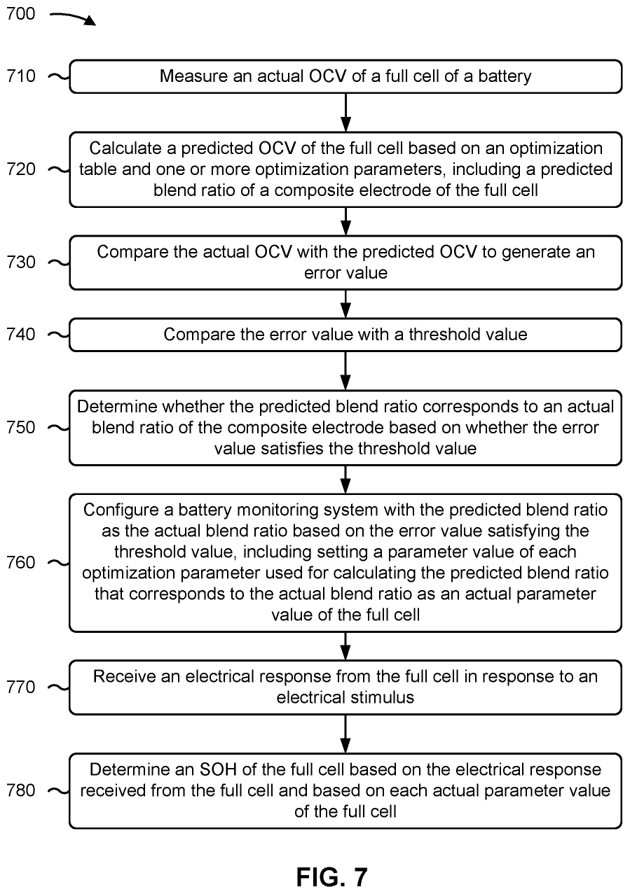

FIG. 7 is a flowchart of an example process 700 associated with method and system for quantifying a composition of a composite battery electrode. One or more process blocks of FIG. 7 may be performed by a controller (e.g., battery pack controller 108). Additionally, or alternatively, one or more process blocks of FIG. 7 may be performed by another device or a group of devices separate from or including the controller, such as the module controller 110 and/or sensors 204.

As shown in FIG. 7, process 700 may include measuring an actual OCV of a full cell of a battery (block 710). For example, the controller may measure the actual OCV of the full cell of the battery, as described above.

As further shown in FIG. 7, process 700 may include calculating a predicted OCV of the full cell based on an optimization table and one or more optimization parameters, including a predicted blend ratio of a composite electrode of the full cell (block 720). For example, the controller may calculate the predicted OCV, as described above.

As further shown in FIG. 7, process 700 may include comparing the actual OCV with the predicted OCV to generate an error value (block 730). For example, the controller may compare the actual OCV with the predicted OCV to generate the error value, as described above.

As further shown in FIG. 7, process 700 may include comparing the error value with a threshold value (block 740). For example, the controller may compare the error value with the threshold value, as described above.

As further shown in FIG. 7, process 700 may include determining whether the predicted blend ratio corresponds to an actual blend ratio of the composite electrode based on whether the error value satisfies the threshold value (block 750). For example, the controller may determine whether the predicted blend ratio corresponds to the actual blend ratio of the composite electrode based on whether the error value satisfies the threshold value, as described above.

As further shown in FIG. 7, process 700 may include configuring a battery monitoring system with the predicted blend ratio as the actual blend ratio based on the error value satisfying the threshold value, including setting a parameter value of each optimization parameter used for calculating the predicted blend ratio that corresponds to the actual blend ratio as an actual parameter value of the full cell (block 760). For example, the controller may configure the battery monitoring system with the predicted blend ratio as the actual blend ratio based on the error value satisfying the threshold value, as described above.

As further shown in FIG. 7, process 700 may include receiving an electrical response from the full cell in response to an electrical stimulus (block 770). For example, the controller may receive the electrical response from the full cell in response to the electrical stimulus, as described above.

As further shown in FIG. 7, process 700 may include determining an SOH of the full cell based on the electrical response received from the full cell and based on each actual parameter value of the full cell (block 780). For example, the controller may determine the SOH, as described above.

Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

### INDUSTRIAL APPLICABILITY

The battery system disclosed herein may determine a composition of a composite electrode of a battery cell in an efficient manner without a tear down of the battery cell. Thus, the battery system may provide a noninvasive method for determining the composition of the composite electrode. Additionally, the battery system may determine the composition of the composite electrode without measuring individual OCV curves of each electrode material of the battery cell, thereby avoiding lengthy characterization times needed for obtaining each individual OCV curve and reducing an overall evaluation time. Additionally, the battery system may reduce an amount of processing power and/or processing resources used to determine the composition of the composite electrode that would otherwise be needed for obtaining each individual OCV curve. As a result, the method may enable the battery system be more efficient in terms of power and processing.

In some implementations, the battery system may determine, based on the composition of the composite electrode, one or more optimization parameters to generate a physics-based model of the battery cell, which may include an overall OCV curve. The method may be employed by a BMS that utilizes the physics-based model to provide estimates of one or more battery parameters or as part of a battery design interface. The battery parameters may include remaining battery capacity, power limits, SOH, and other characteristics, which may be provided to a user via a user interface.

What is claimed is:

1. A battery system, comprising:
a battery comprising a full cell having a composite electrode with a composition that includes an actual blend ratio of one or more electrode materials;
a measurement circuit coupled to the full cell and configured to measure an actual open circuit voltage (OCV) of the full cell;
a memory configured to store a physics-based model for a half-cell comprising a working electrode, and an optimization table; and
at least one processor configured to:
simulate, for each different electrode composition of a plurality of different electrode compositions of the working electrode, the physics-based model with zero current for a first state-of-charge (SOC) until a half-cell potential reaches a first steady state potential,
determine, for each different electrode composition of the plurality of different electrode compositions of the working electrode, a first state-of-lithiation (SOL) of each material of the different electrode composition based on the first steady state potential,
store, in the optimization table for each different electrode composition, the first SOL of each material of the different electrode composition in a first respective table entry linked to the different electrode composition,
calculate a predicted OCV of the full cell based on the optimization table and one or more optimization parameters that include a predicted blend ratio of the composite electrode,
compare the actual OCV with the predicted OCV to generate an error value,
compare the error value with a threshold value,
determine whether the predicted blend ratio corresponds to the actual blend ratio of the composite electrode based on whether the error value satisfies the threshold value, and
configure the measurement circuit with the predicted blend ratio based on the error value satisfying the threshold value.

2. The battery system of claim 1, wherein each different electrode composition of the plurality of different electrode compositions includes a unique set of materials and blend percentages.

3. The battery system of claim 1, wherein the at least one processor is configured to:
iteratively calculate the predicted OCV based on the error value not satisfying the threshold value, wherein the at least one processor is configured to calculate each iteration of the predicted OCV based on a different value set of the one or more optimization parameters,
compare each iteration of the predicted OCV with the actual OCV to generate the error value, and
compare each error value with the threshold value to determine which different value set of the one or more optimization parameters satisfies the threshold value.

4. The battery system of claim 1, wherein the at least one processor is configured to iteratively calculate the predicted OCV using different value sets of the one or more optimization parameters until the error value satisfies the threshold value.

5. The battery system of claim 4, wherein the at least one processor is configured to iteratively calculate the predicted OCV by changing one or more parameter values of the one or more optimization parameters for each iteration.

6. The battery system of claim 1, wherein the at least one processor is configured to determine that the predicted blend ratio is the actual blend ratio of the composite electrode based on the error value being less than the threshold value.

7. The battery system of claim 1, wherein the at least one processor is configured to configure the measurement circuit by setting a parameter value of each optimization parameter used for calculating the predicted blend ratio that corresponds to the actual blend ratio as an actual parameter value of the full cell.

8. The battery system of claim 7, wherein the measurement circuit is configured to calculate a state-of-health (SOH) of the full cell based on each actual parameter value of the full cell.

9. The battery system of claim 1, wherein the one or more optimization parameters include an SOL of an anode electrode of the full cell at 0% SOC of the full cell.

10. The battery system of claim 1, wherein the one or more optimization parameters include a host capacity of an anode electrode of the full cell.

11. The battery system of claim 1, wherein the one or more optimization parameters include a cathode electrode potential of the full cell at 0% SOC and the cathode electrode potential of the full cell at 100% SOC.

12. The battery system of claim 1, wherein the half-cell potential is an OCV of the half-cell.

13. The battery system of claim 1, wherein, for each different electrode composition of the plurality of different electrode compositions, the at least one processor is configured to calculate the first SOL of each material of the different electrode composition as a function of the first SOC and the first steady state potential.

14. The battery system of claim 1, wherein the at least one processor is configured to, for each different electrode composition of the plurality of different electrode compositions:
simulate the physics-based model with zero current for a second SOC until the half-cell potential reaches a second steady state potential,
determine a second SOL of each material of the different electrode composition based on the second steady state potential, and
store, in the optimization table, the second SOL of each material of the different electrode composition in a second respective table entry linked to the different electrode composition.

15. A battery system, comprising:
a battery comprising a full cell having a composite electrode with a composition that includes an actual blend ratio of one or more electrode materials;
a memory configured to store an optimization table, including a plurality of different electrode compositions for a working electrode of a half-cell and, for each different electrode composition, a state-of-lithiation (SOL) of each material of the different electrode composition associated with a steady state potential obtained at a state-of-charge (SOC);
a measurement circuit coupled to the full cell and configured to measure an actual open circuit voltage (OCV) of the full cell; and
at least one processor configured to:
calculate a predicted OCV of the full cell that based on the optimization table and one or more optimization parameters, including a predicted blend ratio of the composite electrode,
compare the actual OCV with the predicted OCV to generate an error value,
compare the error value with a threshold value,
determine whether the predicted blend ratio corresponds to the actual blend ratio of the composite electrode based on whether the error value satisfies the threshold value, and
configure the measurement circuit with the predicted blend ratio based on the error value satisfying the threshold value.

16. The battery system of claim 15, wherein the at least one processor is configured to iteratively calculate the predicted OCV using different value sets of the one or more optimization parameters until the error value satisfies the threshold value.

17. The battery system of claim 15, wherein the one or more optimization parameters includes at least one of an SOL of an anode electrode of the full cell at 0% SOC of the full cell, a host capacity of an anode electrode of the full cell, a cathode electrode potential of the full cell at 0% SOC, or a cathode electrode potential of the full cell at 100% SOC, and
wherein the at least one processor is configured to configure the measurement circuit by setting a parameter value of each optimization parameter used for calculating the predicted blend ratio that corresponds to the actual blend ratio as an actual parameter value of the full cell based.

18. The battery system of claim 15, wherein the battery is a lithium-ion battery and the composite electrode is a cathode electrode of the lithium-ion battery.

19. The battery system of claim 15, wherein the battery is a lithium-ion battery and the composite electrode is an anode electrode of the lithium-ion battery.

20. A method, comprising:
measuring, by a controller, an actual open circuit voltage (OCV) of a full cell of a battery;
calculating, by the controller, a predicted OCV of the full cell based on an optimization table and one or more optimization parameters, including a predicted blend ratio of a composite electrode of the full cell;
comparing, by the controller, the actual OCV with the predicted OCV to generate an error value;
comparing, by the controller, the error value with a threshold value;
determining, by the controller, whether the predicted blend ratio corresponds to an actual blend ratio of the composite electrode based on whether the error value satisfies the threshold value;
configuring, by the controller, a battery monitoring system with the predicted blend ratio as the actual blend ratio based on the error value satisfying the threshold value, including setting a parameter value of each optimization parameter used for calculating the predicted blend ratio that corresponds to the actual blend ratio as an actual parameter value of the full cell;
receiving, by the controller, an electrical response from the full cell in response to an electrical stimulus; and
determining, by the controller, a state-of-health (SOH) of the full cell based on the electrical response received from the full cell and based on each actual parameter value of the full cell.
